(19) United States
(12) Patent Application Publication
(10) Pub. No.: US 2014/0255634 A1
(43) Pub. Date: Sep. 11, 2014

(54) DEVICE HOUSING AND METHOD FOR MAKING THE SAME

(71) Applicants: FIH (Hong Kong) Limited, Kowloon (HK); SHENZHEN FUTAIHONG PRECISION INDUSTRY CO., LTD., Shenzhen (CN)

(72) Inventor: LI-HONG NA, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/974,420

(22) Filed: Aug. 23, 2013

(30) Foreign Application Priority Data
Mar. 11, 2013 (CN) 2013100760683

(51) Int. Cl. H05K 9/00

(52) U.S. Cl. CPC H05K 9/0015
USPC 428/35.8; 264/272.11

(57) ABSTRACT

A housing includes a substrate and a protective layer. The protective layer is formed on the substrate. The substrate includes a first member and a second member, the first member is made of plastic and the second member is made of metal. The protective layer is made of silicone rubber and is formed on the second member of the substrate. The protective layer has a peripheral waterproof portion covering a peripheral edge of the substrate.

### BACKGROUND

1. Technical Field

The present disclosure relates to a device housing and a method for making the device housing.

2. Description of Related Art

Metallic or plastic shells are widely used in many technological fields. One example is a metallic shell used with a portable electronic device (e.g., a mobile phone) for shielding internal electronic components. Typically, exterior surfaces of metallic shells have an attractive smooth texture. However, the exterior surfaces of metallic shells are hard and do not have a comfortable feel. Plastic shells have the same problem.

In another example, plastic shells have a decorative layer, such as, woven or leather formed on the shell for achieving a comfortable feel. However, the decorative layer is not waterproof, and easily becomes worn.

Therefore, there is room for improvement within the art.

### BRIEF DESCRIPTION OF THE FIGURE

Many aspects of the disclosure can be better understood with reference to the following figure. The components in the figure are not necessarily drawn to scale, the emphasis instead being placed upon clearly illustrating the principles of the disclosure.

FIG. 1 is a schematic view of an exemplary embodiment of a device housing.

FIG. 2 is a cross-sectional view of the device housing shown in FIG. 1 taken along line II-II.

### DETAILED DESCRIPTION

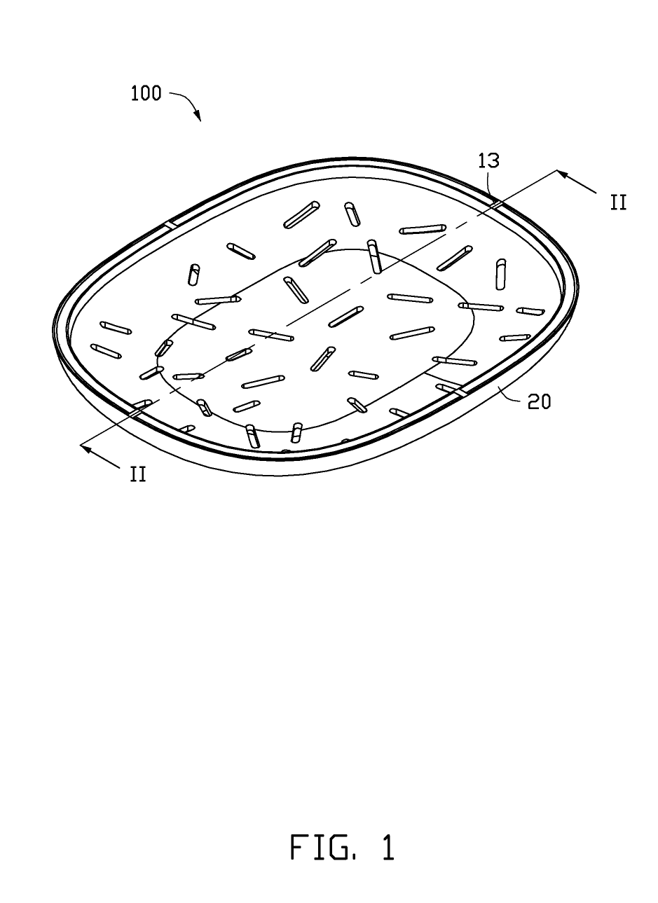

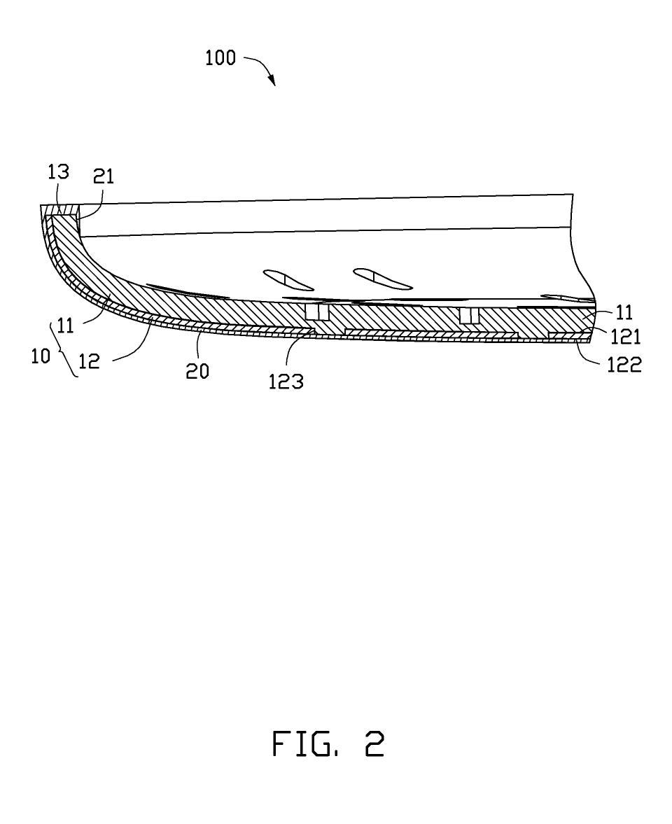

FIGS. 1 and 2 show a housing 100 according to an exemplary embodiment. The housing 10 can be used with an electronic device, (e.g. mobile phone, music player, computer).

The housing 100 includes a substrate 10 and a protective layer 20 formed on the substrate 10.

The substrate 10 includes a first member 11 and a second member 12 integrally formed together. The first member 11 is made of plastic. The plastic can be polycarbonate (PC), or polymethyl methacrylate (PMMA). The second member 12 is made of metal, such as iron or copper. The second member 12 has a first surface 121 and a second surface 122 opposite to each other. The second member 12 is formed by punching metal sheet to a predetermined shape. The second member 12 defines a plurality of through holes 123 communicating with the first surface 121 and the second surface 122. The first member 11 is embedded in the through holes 123 for improving bonding. The through holes 123 may be arranged according to a predetermined pattern for achieving a decorative appearance. In this exemplary embodiment, the first member 11 and the second member 12 are formed by insert molding. The first member 11 is attached to the first surface 121, and portions of the first member 12 is embedded into the through hole 123 of the second member 12 for exposure from the second surface 122.

The protective layer 20 is made of transparent silicone rubber, and is directly formed on the substrate 10. The protective layer 20 contacts with the second surface 122, and has a peripheral waterproof portion 21. The peripheral waterproof portion 21 extends from the second surface 122 of the second member 12 to an inside brim of the first member 11. A thickness of the protective layer 20 is in a range between 0.18 mm to 0.25 mm. In this exemplary embodiment, the thickness of the protective layer 20 is 0.2 mm. Because the protective layer 20 is transparent, patterns of the first member 12 embedded in the through holes 123 can be observed through the protective layer 20. The peripheral waterproof portion 21 covers the peripheral edge of the substrate 10 for preventing water from entering between the first member 11 and the second member 12.

A method for making the device housing 100 may include the following steps:

The substrate 10 is provided. The substrate 10 is made of plastic and metal formed by insert molding. The plastic material constitutes the first member 11 and the metal material constitutes the second member 12. To ensure better bonding, the second surface 122 of the substrate 10 is plasma activated and immersed into an activating agent for about 8 to 10 seconds. Then, the substrate 10 is dried for about 10 minutes at the temperature of about 90° C. To form the peripheral waterproof portion 21, at least one groove 13 is defined on a peripheral edge of the substrate 10. In this exemplary embodiment, four grooves 13 defined on the peripheral edge of the substrate 10. Next, silicone rubber sheet is provided. The substrate 10 with silicone rubber sheet is placed into a mold cavity of a hot pressing mold, and is pressed in a predetermined pressure. The silicone rubber sheet melts to liquid state under the pressure, and is filled in the mold cavity and flows from the grooves 13 toward the inside of the substrate 10 to form the peripheral waterproof portion 21. In this exemplary embodiment, the inside of the mold cavity is heated to about 120° C. The heating time may last for about 2 minutes. The pressing pressure is 50 kg/cm².

Finally, the substrate 10 with the protective layer 20 is removed from the mold cavity. The second member 12 can be observed through the protective layer 20. Additionally, because the protective layer 20 is made of silicon rubber, a soft touch is achieved

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A housing comprising:
a substrate including a first member and a second member, the first member made of plastic and the second member made of metal;
a protective layer made of silicone rubber and formed on the second member of the substrate, the protective layer having a peripheral waterproof portion covering a peripheral edge of the substrate.

2. The housing as claimed in claim 1, wherein the plastic is polycarbonate, or polymethyl methacrylate, the metal is iron or copper.

3. The housing as claimed in claim 2, wherein the second member has a first surface and a second surface opposite to each other, the second member defining a plurality of through holes communicating with the first surface and the second surface, and the first member is embedded in the through holes.

4. The housing as claimed in claim 3, wherein the first member and the second member are formed by insert molding.

5. The housing as claimed in claim 4, wherein the protective layer contacts the second surface, the peripheral waterproof portion extends from the second surface of the second member to an inside brim of the first member.

6. The housing as claimed in claim 5, wherein a thickness of the protective layer is between 0.18 mm to 0.25 mm.

7. A method for making a device housing, comprising:
providing a substrate and a silicone rubber sheet, the substrate defining at least one groove;
placing the substrate with the silicone rubber sheet into a mold cavity of a mold;
pressing the silicone rubber sheet and the substrate and to melt the silicone rubber sheet;
flowing the silicone rubber from the grooves to the inside of the substrate; and
hardening the silicone rubber to form a transparent protective layer.
